(19) United States
(12) Patent Application Publication
(10) Pub. No.: US 2021/0408351 A1
(43) Pub. Date: Dec. 30, 2021

(54) OPTOELECTRONIC SEMICONDUCTOR COMPONENT COMPRISING FIRST CONNECTION REGIONS, AND OPTOELECTRONIC DEVICE

(71) Applicant: OSRAM Opto Semiconductors GmbH, Regensburg (DE)

(72) Inventors: Ivar Tangring, Regensburg (DE); Berthold Hahn, Hemau - Hohenschambach (DE)

(21) Appl. No.: 17/293,049

(22) PCT Filed: Nov. 14, 2019
(86) PCT No.: PCT/EP2019/081352

§ 371 Date: May 12, 2021

(30) Foreign Application Priority Data
Nov. 15, 2018 (DE) 10 2018 128 692.9

(51) Int. Cl. H01L 33/64

(52) U.S. Cl. CPC H01L 33/647; H01L 33/382

(57) ABSTRACT

An optoelectronic semiconductor component having an optoelectronic semiconductor chip for emitting electromagnetic radiation. The optoelectronic semiconductor chip may have a first semiconductor layer, a second semiconductor layer, first and second current spreading layers, electrical connection elements and first connection regions. The first current spreading layer is arranged on a side of the first semiconductor layer facing away from the second semiconductor layer. The first current spreading layer is electrically connected to the first semiconductor layer. The electrical connection elements electrically connect the second semiconductor layer to the second current spreading layer. The first connection regions are connected to the first current spreading layer and extend through the second current spreading layer. An area coverage of the first connection regions in a region between adjacent parts of the second current spreading layer is greater than 20% of the area coverage of the second current spreading layer.

### CROSS-REFERENCE TO RELATED APPLICATIONS

The present application is a national stage entry according to 35 U.S.C. § 371 of PCT Application No. PCT/EP2019/081352 filed on Nov. 14, 2019; which claims priority to German Patent Application Serial No. 10 2018 128 692.9 filed on Nov. 15, 2018; all of which are incorporated herein by reference in their entirety and for all purposes.

### TECHNICAL FIELD

An optoelectronic semiconductor component is disclosed having first connection regions where an area coverage of the first connection regions is arranged in a region between adjacent part of a second current spread layer that where the area coverage is greater than 20% of an area coverage of the second current spreading layer.

### BACKGROUND

A light emitting diode (LED) is a light emitting device based on semiconductor materials. For example, an LED includes a pn junction. When electrons and holes recombine with one another in the regions of the pn junction, due, for example, to a corresponding voltage being applied, electromagnetic radiation is generated.

One issue associated with the operation of LEDs is the generation of heat. In order to increase the efficiency of LEDs, concepts are being sought which allow for the generated heat to be removed in an improved manner.

The object is to provide an improved optoelectronic semiconductor component and an improved optoelectronic device.

According to embodiments, the object is achieved by the subject matter and the method of the independent patent claims. Advantageous enhancements are defined in the dependent claims.

### SUMMARY

An optoelectronic semiconductor component comprises an optoelectronic semiconductor chip which is suitable for emitting electromagnetic radiation. The optoelectronic semiconductor chip comprises a first semiconductor layer of a first conductivity type, a second semiconductor layer of a second conductivity type, first and second current spreading layers, a plurality of electrical connection elements and a plurality of first connection regions. The first semiconductor layer and the second semiconductor layer form a semiconductor layer stack. The first current spreading layer is arranged on a side of the first semiconductor layer facing away from the second semiconductor layer. The first current spreading layer is electrically connected to the first semiconductor layer. The plurality of electrical connection elements is suitable for electrically connecting the second semiconductor layer to the second current spreading layer. The first connection regions are connected to the first current spreading layer and extend through the second current spreading layer. An area coverage of the first connection regions in an area between adjacent parts of the second current spreading layer is greater than 20% of an area coverage of the second current spreading layer.

According to further embodiments, an optoelectronic semiconductor component comprises an optoelectronic semiconductor chip which is suitable for emitting electromagnetic radiation. The optoelectronic semiconductor chip comprises a first semiconductor layer of a first conductivity type, a second semiconductor layer of a second conductivity type, a first and a second current spreading layer, a plurality of electrical connection elements and a plurality of first connection regions. The first semiconductor layer and the second semiconductor layer form a semiconductor layer stack. The first current spreading layer is arranged on a side of the first semiconductor layer facing away from the second semiconductor layer. The first current spreading layer is electrically connected to the first semiconductor layer. The plurality of electrical connection elements is suitable for electrically connecting the second semiconductor layer to the second current spreading layer. The first connection regions are connected to the first current spreading layer and extend through the second current spreading layer. An area coverage of the first connection regions in an area between adjacent parts of the second current spreading layer is greater than 20% of an area coverage of the first current spreading layer.

According to the embodiments described in this application, the second current spreading layer is suitable for interconnecting the plurality of electrical connection elements.

The second current spreading layer may, for example, be partly designed as a grid. The second current spreading layer may be designed as a non-continuous layer in this grid area, but rather, for example, be interrupted at constant intervals. For example, the second current spreading layer may be interrupted by the electrical connection regions. As a result, a large part of the thermal heat generated in the optoelectronic semiconductor chip may be dissipated via the first connection regions.

The semiconductor chip comprises, for example, a plurality of light-generating regions which are arranged between the electrical connection elements. According to embodiments, the first connection regions are insulated from the second current spreading layer via an insulating layer.

The first current spreading layer may be arranged between the second current spreading layer and the first semiconductor layer.

According to embodiments, the optoelectronic semiconductor component may furthermore comprise a transparent substrate over the second semiconductor layer on a side facing away from the first semiconductor layer. For example, a part of the second current spreading layer may be arranged outside the light-generating regions.

The optoelectronic semiconductor component may furthermore comprise a first connecting post, which is electrically connected to the first connecting regions, and a second connecting post, which is electrically connected to the second current spreading layer, wherein the first and second connecting posts are insulated from one another by an insulating material.

According to embodiments, the optoelectronic semiconductor component further comprises a first contact region which is connected to the first current spreading layer, and a second contact region which is connected to the second current spreading layer, the first and the second contact regions being arranged in the area of a second main surface of the optoelectronic semiconductor component.

According to embodiments, the optoelectronic semiconductor component comprises a first contact region which directly adjoins the first connection regions, and a second contact region which directly adjoins the second current spreading layer. In this case, the first contact region and the second contact region are arranged in the region of a second main surface of the optoelectronic semiconductor component.

The optoelectronic semiconductor component may furthermore include a first contact region which is electrically connected to the first connection regions, and a second contact region which is electrically connected to the second current spreading layer. The second contact region may be connectable from a first main surface of the optoelectronic semiconductor component. The first contact region may be connectable from a second main surface of the optoelectronic semiconductor component.

According to further embodiments, the optoelectronic semiconductor component may furthermore comprise a first contact region which is electrically connected to the first connection regions, and a second contact region which is electrically connected to the second current spreading layer. In this case, the second and the first contact regions may be connectable from a first main surface of the optoelectronic semiconductor component.

According to further embodiments, the optoelectronic semiconductor component may furthermore include a second contact region which is connected to the second current spreading layer and is arranged laterally spaced apart from the first contact region. In this case, at least a part of the second contact region may not vertically overlap with the first semiconductor layer.

According to further embodiments, an optoelectronic semiconductor component comprises an optoelectronic semiconductor chip which is suitable for emitting electromagnetic radiation. The optoelectronic semiconductor chip comprises a first semiconductor layer of a first conductivity type, a second semiconductor layer of a second conductivity type, a first and a second current spreading layer and a plurality of electrical connection elements. The first semiconductor layer and the second semiconductor layer form a semiconductor layer stack. The first current spreading layer is arranged on a side of the first semiconductor layer facing away from the second semiconductor layer. The first current spreading layer is electrically connected to the first semiconductor layer. The plurality of electrical connection elements is suitable for electrically connecting the second semiconductor layer to the second current spreading layer. The optoelectronic semiconductor chip furthermore comprises a first contact region which is connected to the first current spreading layer, and a second contact region which is connected to the second current spreading layer. In this case, the second contact region is connectable from a first main surface of the optoelectronic semiconductor component, and the first contact region is connectable from a second main surface of the optoelectronic semiconductor component.

According to further embodiments, an optoelectronic semiconductor component comprises an optoelectronic semiconductor chip which is suitable for emitting electromagnetic radiation. The optoelectronic semiconductor chip comprises a first semiconductor layer of a first conductivity type, a second semiconductor layer of a second conductivity type, first and second current spreading layers and a plurality of electrical connection elements. The first semiconductor layer and the second semiconductor layer form a semiconductor layer stack. The first current spreading layer is arranged on a side of the first semiconductor layer facing away from the second semiconductor layer. The first current spreading layer is electrically connected to the first semiconductor layer. The plurality of electrical connection elements is suitable for electrically connecting the second semiconductor layer to the second current spreading layer. The optoelectronic semiconductor chip furthermore comprises a first contact region which is connected to the first current spreading layer, and a second contact region, which is connected to the second current spreading layer. The second and the first contact regions are connectable from a first main surface of the optoelectronic semiconductor component.

According to embodiments, an optoelectronic device comprises the optoelectronic semiconductor component described above. The optoelectronic device may, for example, be selected from car headlights, projectors and lighting devices.

According to further embodiments, an optoelectronic device may comprise a plurality of optoelectronic semiconductor components as described above.

The optoelectronic device may furthermore comprise a plurality of second optoelectronic semiconductor components which have a different structure than the optoelectronic semiconductor components. For example, the optoelectronic device may be a lighting device for plants.

### BRIEF DESCRIPTION OF THE DRAWINGS

The accompanying drawings serve to provide an understanding of exemplary embodiments. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1 shows a vertical cross-sectional view of an optoelectronic semiconductor component according to embodiments.

FIGS. 2 to 4 show vertical cross-sectional views of optoelectronic semiconductor components according to further embodiments.

FIGS. 5A to 5C each show horizontal cross-sectional views of the optoelectronic semiconductor component in different planes.

FIGS. 6A to 6C each show horizontal cross-sectional views of the optoelectronic semiconductor component according to embodiments in different planes.

FIGS. 7A and 7B each show a view of an optoelectronic device.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since there are also other exemplary embodiments, and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material or of an insulating material, for example sapphire. Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, phosphide semiconductor compounds by means of which, for example, green or longer-wave light may be generated, such as GaAsP, AlGaInP, GaP, AlGaP, and other semiconductor materials such as AlGaAs, SiC, ZnSe, GaAs, ZnO, Ga₂O₃, diamond, hexagonal BN and combinations of the materials mentioned. The stoichiometric ratio of the ternary compounds may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The terms “lateral” and “horizontal”, as used in the present description, are intended to describe an orientation or alignment which extends essentially parallel to a first surface of a semiconductor substrate or semiconductor body. This may be the surface of a wafer or a chip (die), for example.

The horizontal direction may, for example, be in a plane perpendicular to a direction of growth when layers are grown.

The term “vertical” as used in this description is intended to describe an orientation which is essentially perpendicular to the first surface of the semiconductor substrate or semiconductor body. The vertical direction may correspond, for example, to a direction of growth when layers are grown.

To the extent used herein, the terms “have”, “include”, “comprise”, and the like are open-ended terms that indicate the presence of said elements or features, but do not exclude the presence of further elements or features. The indefinite articles and the definite articles include both the plural and the singular, unless the context clearly indicates otherwise.

In the context of this description, the term “electrically connected” means a low-ohmic electrical connection between the connected elements. The electrically connected elements need not necessarily be directly connected to one another. Further elements may be arranged between electrically connected elements.

The term “electrically connected” also encompasses tunnel contacts between the connected elements.

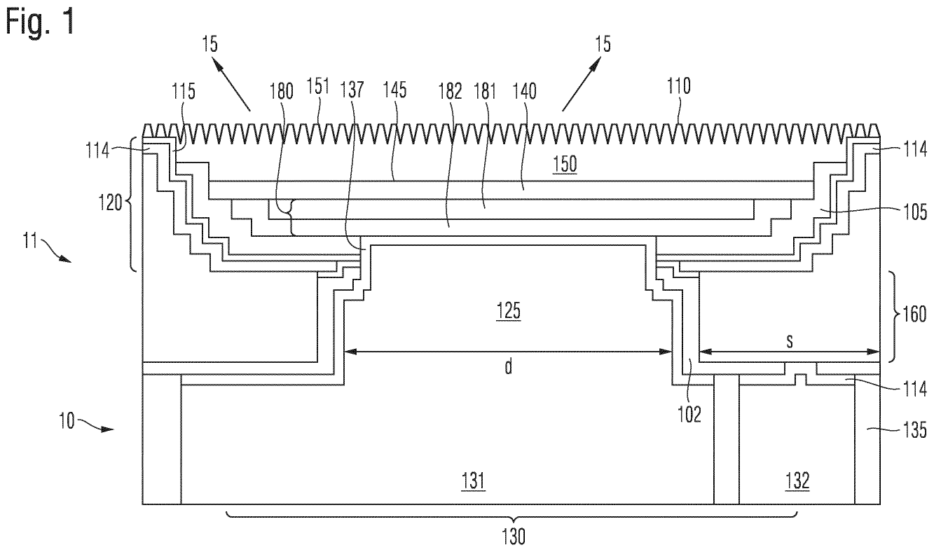

FIG. 1 shows a vertical cross-sectional view of an optoelectronic semiconductor component 10 according to embodiments. The optoelectronic semiconductor component 10 comprises an optoelectronic semiconductor chip 11. The optoelectronic semiconductor chip 11 is suitable for emitting electromagnetic radiation 15. The optoelectronic semiconductor chip 11 comprises a first semiconductor layer 140 of a first conductivity type, for example p-type, and a second semiconductor layer 150 of a second conductivity type, for example n-type. The optoelectronic semiconductor chip 11 furthermore comprises a first and a second current spreading layer 180, 160, a plurality of electrical connection elements 120 and a plurality of first connection regions 125. The first semiconductor layer 140 and the second semiconductor layer 150 form a semiconductor layer stack. The first current spreading layer 180 is arranged on a side of the first semiconductor layer 140 facing away from the second semiconductor layer 150 and is electrically connected to the first semiconductor layer 140. The plurality of electrical connection elements 120 is suitable for electrically connecting the second semiconductor layer 150 to the second current spreading layer 160. The first connection regions are connected to the first current spreading layer and extend through the second current spreading layer. An area coverage of the first connection regions 125 in an area between adjacent parts of the second current spreading layer 160 is greater than 20% of the area coverage of the current spreading layer 160.

According to embodiments, the generated electromagnetic radiation 15 may be emitted via a first main surface 151 of the second semiconductor layer 150. For example, the first main surface 151 of the second semiconductor layer 150 may be roughened in order to increase a light extraction efficiency. An active zone 145 may be arranged between the first semiconductor layer 140 and the second semiconductor layer 150. For example, an active zone may be arranged between the first and second semiconductor layers. The active zone may, for example, comprise a pn junction, a double heterostructure, a single quantum well structure (SQW, single quantum well) or a multiple quantum well structure (MQW, multi quantum well) for generating radiation. The term “quantum well structure” does not imply any particular meaning here with regard to the dimensionality of the quantization. Therefore it includes, among other things, quantum wells, quantum wires and quantum dots as well as any combination of these structures.

The first current spreading layer 180 is arranged adjacent to the first semiconductor layer 140. The first current spreading layer 180 may comprise several layers, for example. For example, the first current spreading layer 180 may comprise a layer 181 made of silver and one or more further conductive layers 182. For example, the further conductive layer 182 may comprise a thin layer made of a metal such as platinum, palladium, titanium, nickel, chromium, which may prevent diffusion of other metals. The further conductive layer may also include a highly conductive layer, for example made of Au, Cu, Ag or Al. For example, conductive layer 182 may encapsulate the silver layer. In addition, for example, a conductive oxide layer may be arranged between the silver layer 181 and the first semiconductor layer 140 in order to provide improved contact to the first semiconductor layer.

The second current spreading layer 160 may be insulated from the first current spreading layer 180 and the first semiconductor layer 140 via an insulating layer 105. The second current spreading layer 160 is connected to the second semiconductor layer 150 via electrical connection elements 120. For example, a plurality of electrical connection elements 120 may be provided, and light-generating regions 130 in which electromagnetic radiation is generated are arranged, for example, between adjacent electrical connection elements 120. For example, a conductive layer that forms the second current spreading layer 160 as well as the electrical connection elements 120 may have Ti, WN, or a metal stack composed of these layers. The metal layer stack may furthermore include gold or platinum.

The first connection regions 125 are connected to the first current spreading layer 180. The first connection regions 125 are insulated from the second current spreading layer 160 via an insulating material 102, for example. Furthermore, the electrical connection elements 120 are each insulated both from the first current spreading layer 180 and from the first semiconductor layer 140 by an insulating material 105. Examples of the insulating material 102, 105 include, without limitation, silicon oxide, silicon nitride, aluminum oxide, and combinations of these materials.

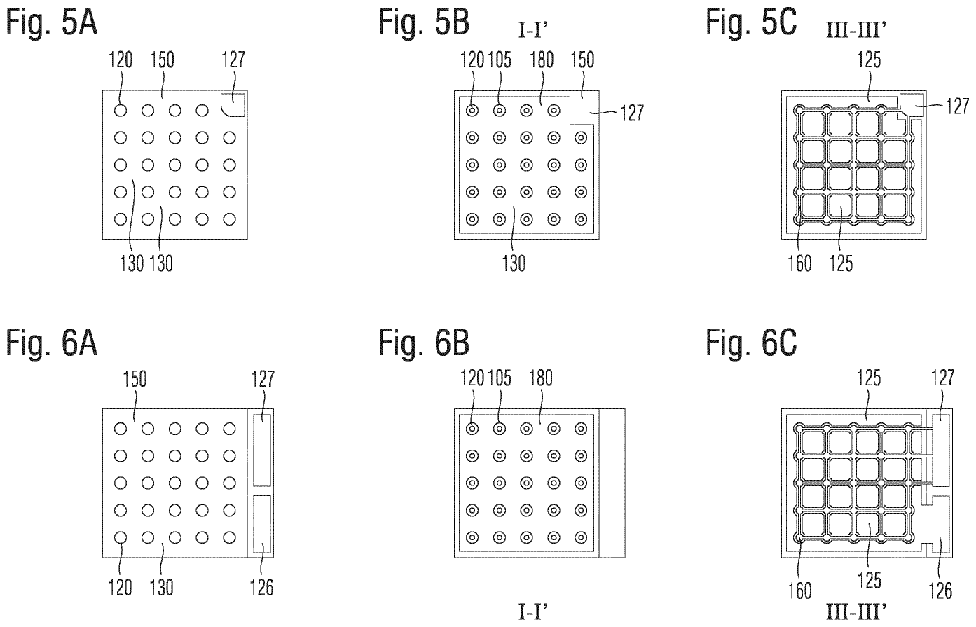

According to a non-limiting embodiment, it is now provided that an area coverage of the first connection regions 125 in a region between adjacent parts of the second current spreading layer is greater than 20% of an area coverage of the second current spreading layer 160. The optoelectronic semiconductor component comprises a plurality of first connection regions 125. The area coverage of the first connection regions 125 therefore relates to the sum of the individual areas of all first connection regions 125 in a plane. Furthermore, the term “area coverage of the second current spreading layer” denotes the horizontal portion of the second current spreading layer 160 on which electrically conductive material, which is electrically connected to the second current spreading layer, is present. According to embodiments, the area coverage may be greater than 50% or even greater than 80% of the area coverage of the second current spreading layer 160. As a result, a large part of the thermal heat generated in the optoelectronic semiconductor chip 11 may be dissipated via the first connection regions 125. The feature of the ratios of the surface occupancy will be explained again with reference to FIGS. 5C and 6C, which each show horizontal cross-sectional views.

FIG. 1 also shows a horizontal dimension d of the first connection regions 125 in an area between adjacent parts of the second current spreading layer and a horizontal dimension s of the second current spreading layer 160. For example, a horizontal dimension d of the first connection regions 125 in a region between adjacent parts of the second current spreading layer may be greater than 20% of a horizontal dimension s of the second current spreading layer 160. The optoelectronic semiconductor component comprises a plurality of first connection regions 125. The horizontal dimension d of the first connection regions 125 therefore relates to the sum of the individual dimensions of all first connection regions 125 in a plane. Furthermore, the term “horizontal dimension of the second current spreading layer” denotes the horizontal portion of the second current spreading layer 160 on which electrically conductive material, which is electrically connected to the second current spreading layer, is present. According to embodiments, the horizontal dimension d of the first connection regions may be greater than 50% or even greater than 80% of the horizontal dimension s of the second current spreading layer 160.

According to an alternative approach, an optoelectronic semiconductor component 10 comprises an optoelectronic semiconductor chip 11 which is suitable for emitting electromagnetic radiation 15. The optoelectronic semiconductor chip 11 comprises a first semiconductor layer 140 of a first conductivity type, a second semiconductor layer 150 of a second conductivity type, first and second current spreading layers 180, 160, a plurality of electrical connection elements 120 and a plurality of first connection regions 125. The first semiconductor layer 140 and the second semiconductor layer 150 form a semiconductor layer stack. The first current spreading layer 180 is arranged on a side of the first semiconductor layer 140 facing away from the second semiconductor layer 150. The first current spreading layer 180 is electrically connected to the first semiconductor layer 140. The plurality of electrical connection elements 120 is suitable for electrically connecting the second semiconductor layer 150 to the second current spreading layer 160. The first connection regions 125 are connected to the first current spreading layer 180 and extend through the second current spreading layer 160. An area coverage of the first connection regions 125 in a region between adjacent parts of the second current spreading layer 160 is greater than 20% of an area coverage of the first current spreading layer 180.

According to further embodiments, an area coverage of the first connection regions 125 in a region between adjacent parts of the second current spreading layer 160 may be greater than 20% of an area coverage of the silver layer 181, which may be arranged in direct contact with the first semiconductor layer 140. The area coverage may also be at least 40% or at least 60 or 80% of the area coverage of the silver layer 181.

During operation of the optoelectronic semiconductor component, an electrical voltage is applied to the LED via the second current spreading layer 160 and the first current spreading layer 180 connected via the first connection regions 125. In this case, an electrical current path extends from the second current spreading layer 160 via the electrical connection elements 120 to the second semiconductor layer 150 and is spread via the latter along the active zone 125 or along the interface with the first semiconducting layer 140. Correspondingly, the heat development takes place essentially in the region of the active zone or the interface between the first and second semiconductor layers 140, 150. As the horizontal dimension d of the first connecting region 125 has a corresponding magnitude, the heat may be dissipated particularly effectively in the region in which it arises. Accordingly, heating-up of the optoelectronic semiconductor component may be avoided or suppressed. As a result, the efficiency of the optoelectronic semiconductor component is increased.

This is advantageous, for example, in cases in which the optoelectronic semiconductor component is a so-called high-performance component with a current density of several A/mm². As a further result, the conversion efficiency may also be improved when using a converter material for changing the length of the light wavelength output by the optoelectronic semiconductor component. Furthermore, the overall service life of the component may be increased since, for example, polymers and other sensitive encapsulation or packaging materials age less quickly. As a further consequence, operating currents may be increased without exceeding a maximum temperature of the component.

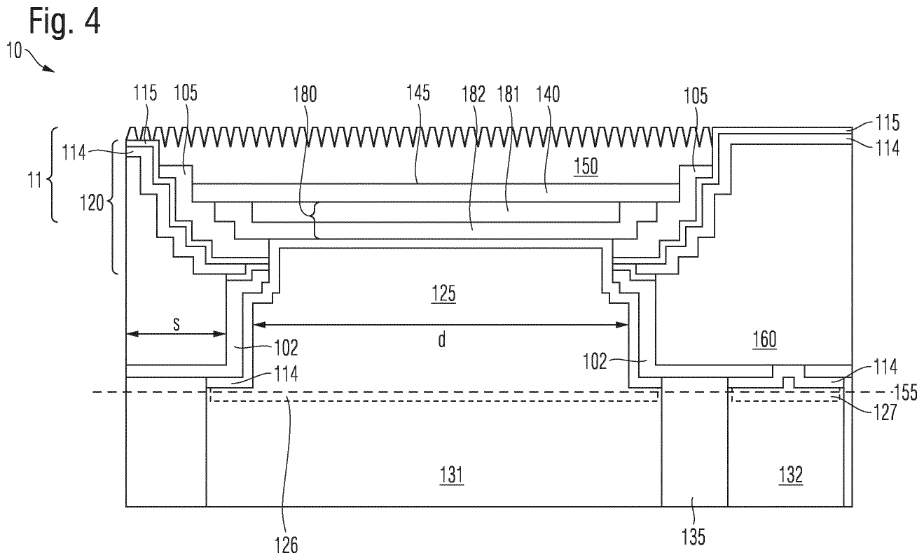

As further illustrated in FIG. 1, according to an embodiment, the optoelectronic semiconductor component 10 may further comprise a first connecting post 131 and a second connecting post 132, which may be isolated from one another by an insulating carrier material 135, for example. The first connecting post 131 is connected to the first connecting regions 125 in an electrically conductive manner. Furthermore, the second connecting post 132 is connected to the second current spreading layer 160 in an electrically conductive manner. For example, the connecting posts may have a correspondingly thick nickel layer. For example, the thickness of the nickel layer may be more than 100 μm, for example more than 120 μm. Instead of nickel, a metal with better thermal conductivity, for example copper, may of course be used in order to further improve heat dissipation. According to further embodiments, the first and second connecting posts may also be dispensed with. As will be discussed below with reference to FIG. 4, the optoelectronic semiconductor component 10 may, for example, also be mounted or soldered directly via the contact region in contact with the first connection regions 125 or in contact with the second current spreading layer 160.

According to the embodiments illustrated in FIG. 1, both first and second current spreading layers 180, 160 may each be contacted from a rear side of the optoelectronic semiconductor chip, that is to say from a side that is not the light-emitting surface.

Furthermore, for example, a contact layer 115, for example made of a conductive oxide, for example zinc oxide, may be provided between the second semiconductor layer 150 and the conductive layer 114. The conductive layer 114 may, for example, be a seed layer for a galvanic process to be carried out subsequently to form a conductive layer which, for example, forms the electrical connection element and the second current spreading layer 160. The seed layer 114 may also be provided between the first current spreading layer 180 and the first connection regions 125 in order to promote the galvanic formation of the first connection regions 125. The seed layer 114 may furthermore be arranged between the second current spreading layer 160 and the second connecting post 132. For example, the seed layer 114 may include any electrically conductive material. The seed layer 114 may be composed of a metal that does not oxidize, that is to say is chemically inert, for example gold or nickel.

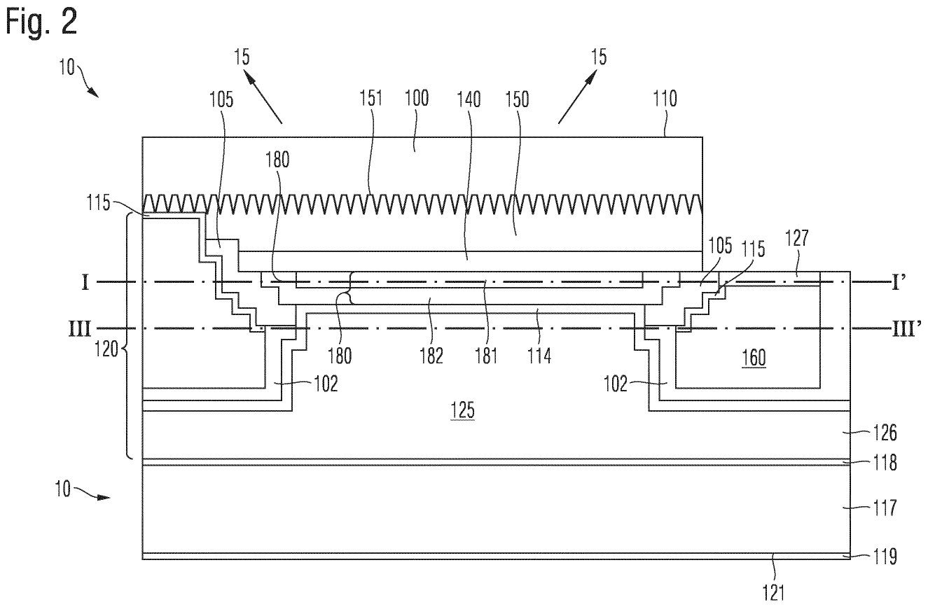

FIG. 2 shows a vertical cross-sectional view of an optoelectronic semiconductor component in accordance with further embodiments. The optoelectronic semiconductor component shown in FIG. 2 is constructed in a way similar to that the semiconductor component shown in FIG. 1. In addition, a transparent substrate 100 is arranged adjoining the first main surface 151 of the second semiconductor layer 150. For example, the transparent substrate may be a sapphire substrate, which is used, for example, as a growth substrate for epitaxial growth of the second and first semiconductor layers. For example, in this case, the sapphire substrate 100 may further distribute the heat generated in the optoelectronic semiconductor chip. Electromagnetic radiation 15 emitted by the optoelectronic semiconductor chip 11 may, for example, be emitted via the first main surface of the transparent substrate and also via its side surfaces.

According to embodiments illustrated in FIG. 2, the optoelectronic semiconductor component furthermore comprises a second contact region 127. The second contact region 127 is connected to the second current spreading layer 160. The second contact region 127 is connectable from a first main surface 110 of the optoelectronic semiconductor component. Furthermore, a first contact region 126, which is connected to the first current spreading layer 180, is connectable from a second main surface of the optoelectronic semiconductor component. For example, the first contact region 126 may comprise a flat or partially flat conductive layer which is in contact with the first connection regions 125.

As shown in FIG. 2, the optoelectronic semiconductor chip 11 may be mounted on a carrier 117. For example, the carrier 117 may comprise doped silicon, as a result of which an all-over contact with the first contact region 126 may be provided. For example, a conductive layer 119 may be arranged on a second main surface 121 of the carrier 117. A first conductive layer 118 may be provided between the carrier material 117 and the first contact region 126. For example, the carrier 117 may be provided to impart mechanical stability to the optoelectronic semiconductor component 10. A layer thickness of the carrier 117 may be selected accordingly. According to further embodiments, the optoelectronic semiconductor chip 11 may be soldered directly onto a ceramic carrier on which conductor tracks, for example made of copper, are applied. As a result, the heat dissipation may be further improved.

The optoelectronic semiconductor component shown in FIG. 2 therefore represents a vertical optoelectronic semiconductor component in which one of the two semiconductor layers is connectable from a first main surface or front side of the semiconductor component and the other semiconductor layer is contactable from a second main surface or rear side of the semiconductor component. In optoelectronic semiconductor components that include gallium nitride as semiconductor layers, the contact region which is connected to the p-layer is usually arranged in the region of the first main surface 110 of the optoelectronic semiconductor component. The contact region which is connected to the n-semiconductor layer is usually arranged in the region of the second main surface of the optoelectronic semiconductor component. In the case of optoelectronic semiconductor components which contain a semiconductor material other than GaN, for example phosphide compound semiconductors, on the other hand, the polarity is reversed. That is to say, the p-terminal is located on the second main surface of the semiconductor component, and the n-terminal is arranged in the region of the first main surface 110 of the optoelectronic semiconductor component. As a result of the arrangement and polarity of the contact regions being now adapted to the polarity of the contact regions in optoelectronic semiconductor components with other semiconductor materials, as illustrated in FIG. 2, it is possible in a simple manner to provide or replace the corresponding optoelectronic semiconductor chips in optoelectronic semiconductor components comprising different semiconductor chips (i.e. based on different semiconductor materials, for example).

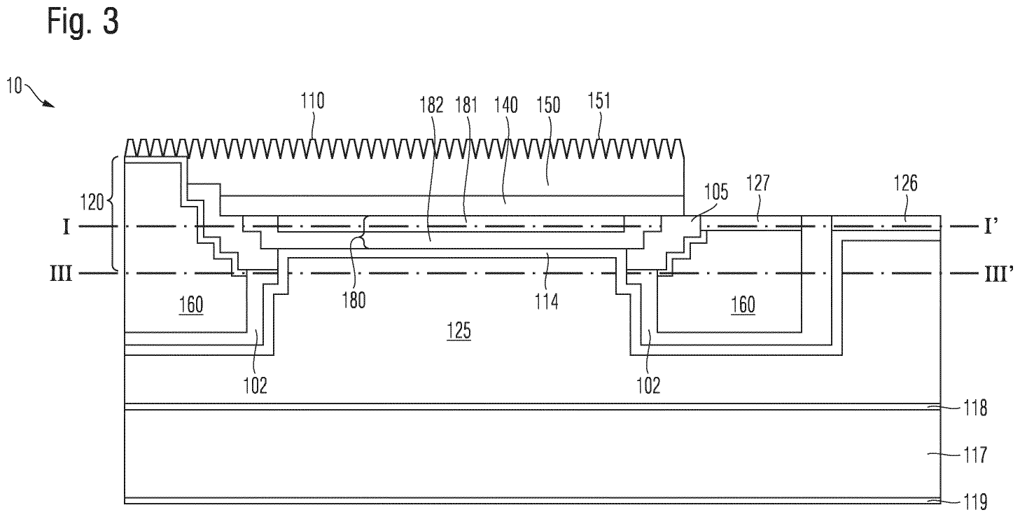

FIG. 3 shows a vertical cross-sectional view of an optoelectronic semiconductor component in accordance with further embodiments. Components of the optoelectronic semiconductor component illustrated in FIG. 3 are similar or identical to the components illustrated in FIGS. 1 and 2. Deviating from the embodiment shown in FIG. 2, the first contact region 126 may in this case be contacted from one side of the first main surface 110 of the optoelectronic semiconductor component 10. That is to say, the first contact region 126 and the second contact region 127 are each placed on a front side of the optoelectronic semiconductor component 10. According to embodiments, the optoelectronic semiconductor chip 11 may be placed on an insulating carrier 117. The insulating carrier 117 may be a carrier of high thermal conductivity. For example, the carrier 117 may be made from an AlN or Si₃N₄ ceramic. For example, the conductive layer representing the first connection regions 125 may be applied over a large area. A first contact region 126 is connected in an electrically conductive manner to the first connection regions 125 via this conductive layer. For example, the second contact region 127 may be formed by a conductive layer over the second current spreading layer 160.

In addition, a first conductive layer 118 may be arranged between the insulating carrier 117 and the conductive material which produces the electrical connection between the first connection regions 125 and the first contact region. According to embodiments shown in FIG. 3, a conductive layer 119 may furthermore be applied in the region of a rear side of the optoelectronic semiconductor chip 11.

FIG. 4 shows a vertical cross-sectional view of an optoelectronic semiconductor component 10 in accordance with further embodiments. According to the embodiments illustrated in FIG. 4, an attempt is made to make the connection between the first current spreading layer 180 and the first connection regions 125 as large as possible. Correspondingly, a horizontal dimension d of the first connection regions 125, according to these embodiments, may be even larger than a horizontal dimension s of the second current spreading layer 160. According to these embodiments, an area coverage of the first connection regions 125 may also be larger than an area coverage of the second current spreading layer. Further elements of the embodiment of FIG. 4 are similar to components that have been discussed with reference to FIGS. 1 to 3. According to embodiments shown in FIG. 4, a part of the second current spreading layer 160 is arranged in a region which does not overlap with the second semiconductor layer 150 in the vertical direction. That is to say, with respect to a vertical direction, the second semiconductor layer 150 is not arranged over the entire second current spreading layer 160. A part of the second current spreading layer 160 is arranged in the horizontal direction between adjacent parts of the second semiconductor layer 150. In a corresponding manner, the second connecting post 132, which is connected to the second current spreading layer 160, or at least a part of the second connecting post 132 is arranged outside a region in which the first and the second semiconductor layers 140, 150 are present. Furthermore, the first connection regions 125 are arranged in such a way that the largest possible part of the active zone 145 or the interface between the first and second semiconductor layers 140, 150 overlap with the first connection regions 125. In this way, particularly efficient heat dissipation is achieved.

In other words, the semiconductor component is made to be slightly larger than the area of the semiconductor chip 11. The second connecting post 132 is accommodated in this additional surface area, so that the first connecting post 131, which is connected to the first connecting regions 125, has the greatest possible surface area.

For example, an electrically insulating material, for example made of epoxy resin, may be arranged between the first and the second connecting posts 131, 132.

According to further embodiments, the lower part of the optoelectronic semiconductor component 10 along the dividing line 155 may be omitted. In this case, for example, a first contact region 126 (shown in dashed lines) may be formed in contact with the first connection regions 125. Furthermore, a second contact region 127 (shown in dashed lines) may be formed instead of the second connecting post 132. For example, such an optoelectronic semiconductor element may be soldered directly onto a ceramic carrier which, for example, comprises soldering points. For example, the first contact region 126 and the second contact region 127 may have a layer thickness of approximately 1 to 2 μm.

When removing the lower part of the optoelectronic component, for example, a laser lift-off to remove the growth substrate may be carried out at the package level. Furthermore, the first main surface 151 of the second semiconductor layer 150 may be roughened at the package level.

As shown in FIG. 4, the optoelectronic semiconductor component 10 is larger than the area within which optoelectronic radiation is generated.

FIGS. 5A to 5C show cross-sectional views in different planes of the optoelectronic semiconductor component according to embodiments. These figures are intended to illustrate which regions of the optoelectronic semiconductor component are respectively available for heat dissipation and how the individual layers are designed in a horizontal plane.

FIG. 5A is a top view of the second semiconductor layer 150 and the second contact region 127, as shown for example in FIG. 2. The second semiconductor layer 150 is formed to be flat. Regions in which the electrical connection elements 120 contact the second semiconductor layer 150 are also shown in FIG. 5A. A light-generating region 130 is arranged in each case between adjacent electrical connection elements 120.

FIG. 5B shows a plan view of the first current spreading layer 180 and illustrates the regions in which the first current spreading layer 180 contributes to the dissipation of heat. A position of this plan view is, for example, indicated in FIG. 2 between I and I′. As may be seen, the first current spreading layer 180 is formed over a large area and is interrupted by electrical connecting elements 120.

As may also be seen, the area coverage by the electrical connection elements 120 is significantly smaller than the area of the first current spreading layer 180. As a result of the electrical connection elements 120 being spatially separated from the light-generating regions 130, as explained above, heat dissipation via the electrical connection elements 120 is generally not very efficient. As a result, the performance of the optoelectronic semiconductor component is impaired to an insignificant extent by impairment of the heat dissipation via the electrical connection elements 120.

FIG. 5C illustrates the dissipation of heat via the second current spreading layer 160 and the first connection regions 125 in a region between III and III′, as shown in FIG. 2. In this region, the second current spreading layer 160 is designed as a grid, in which the second current spreading layer 160 is interrupted by the electrical connection regions 125. For example, by increasing the layer thickness of the current spreading layer 160, a uniform spreading of the electric current may be ensured. For example, the layer thickness of the current spreading layer may be more than 500 nm, for example more than 1 μm, for example 3 to 7 μm or 3 to 10 μm.

FIG. 5C furthermore shows a plan view in a region in which the horizontal extent of the first connecting regions 125 is minimal. That is to say, the region shown in FIG. 5C virtually represents the thermal bottleneck. As shown particularly in FIG. 5C, the first connection regions 125 are formed over a large area compared to the size of the semiconductor chip 11. Accordingly, efficient heat dissipation is possible. As shown in FIG. 5C, an area coverage of the first connection regions 125 in a region between adjacent parts of the second current spreading layer 160 is greater than 20% of the area coverage of the second current spreading layer 160. For example, the area coverage may also be greater than 20%, for example greater than 40% or greater than 60% or greater than 80% of the area coverage of the second current spreading layer 160.

FIGS. 6A to 6C are corresponding views in the case of the optoelectronic semiconductor component shown in FIG. 3. As shown in FIG. 6A, the first contact region 126 and the second contact region 127 are formed in the region of the first main surface 110 of the optoelectronic semiconductor component. The second semiconductor layer is formed over the entire area, as shown in FIG. 5A, and connected to the second current spreading layer 160 in places via electrical connection elements 120. Light-generating regions 130 are each arranged between adjacent electrical connection elements 120. As shown in FIG. 6B, the entire area of the first current spreading layer 180 in the region of the entire semiconductor chip contributes to the dissipation of heat.

The electrical connection elements 120 also contribute to the dissipation of heat in the entire area of the semiconductor chip. As shown in FIG. 6C, a part of the first contact region 126 arranged outside the chip area additionally contributes to the dissipation of heat. Furthermore, the heat dissipation takes place in the entire area of the semiconductor chip via the first connection regions 125. As shown in FIG. 6C, an area coverage of the first connection regions 125 in a region between adjacent parts of the second current spreading layer 160 is greater than 20% of the area coverage of the second current spreading layer 160. For example, the area coverage may also be greater than 20%, for example greater than 40% or greater than 60% or greater than 80% of the area coverage of the second current spreading layer 160.

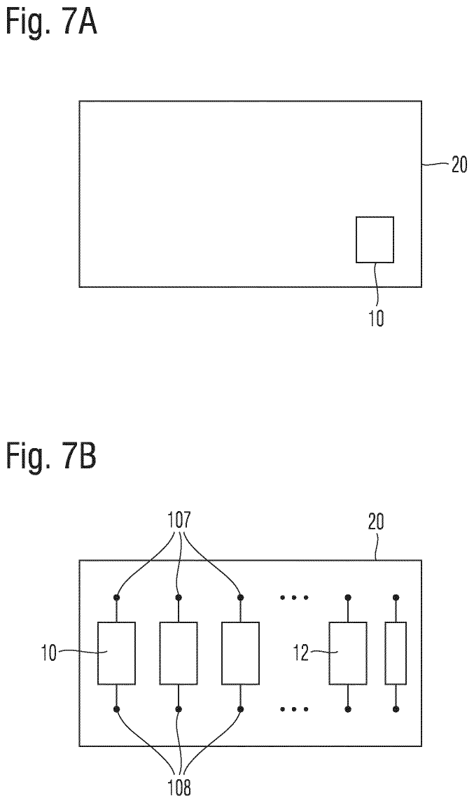

FIG. 7A shows a schematic view of an optoelectronic device 20. The optoelectronic device 20 comprises the optoelectronic semiconductor component 10 as described above. For example, the optoelectronic device may be a device of high luminance that may be operated, for example, at a high current intensity. Specific examples include car headlights, projectors, and special high-luminance lighting devices.

Furthermore, as illustrated in FIG. 7B, the optoelectronic device 20 comprises a plurality of optoelectronic semiconductor components 10. The optoelectronic device 20 may furthermore comprise second optoelectronic semiconductor components 12 which, for example, may be based on a different semiconductor material than the optoelectronic semiconductor components 10 and may have a different structure. For example, the optoelectronic device may comprise a plurality of first connections 107 and a plurality of second connections 108. The first connections may be positive connections, for example, the second connections may be negative connections, for example. For example, the first connections 107 may enable contacting from a second main surface of the optoelectronic semiconductor components 10. The second connections 108 may enable contacting from a first main surface of the optoelectronic semiconductor components. According to embodiments, the first contact regions 126 of the optoelectronic semiconductor components 10 may be present on the second main surface, and the second contact regions 127 of the optoelectronic semiconductor components 10 are present on the first main surface. In this way, the optoelectronic semiconductor components 10 may be contacted in a manner similar to LEDs which are based on phosphide semiconductor compounds. As a result, LEDs in the optoelectronic device 20 may be exchanged in a simple manner. For example, such optoelectronic devices 20 may be used to illuminate plants. In such devices, for example, a plurality of red and blue LEDs may be connected in series.

Although specific embodiments have been illustrated and described herein, those skilled in the art will recognize that the specific embodiments shown and described may be replaced by a plurality of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor component
11 optoelectronic semiconductor chip
12 second optoelectronic semiconductor component
15 emitted electromagnetic radiation
20 optoelectronic device
100 transparent substrate
102 insulating layer
105 insulating layer
107 first terminal
108 second terminal
110 first main surface of the semiconductor component
114 conductive layer (seed layer)
115 contact layer
117 carrier
118 first conductive layer
119 second conductive layer
120 electrical connection element
121 second main surface
125 first connection region
126 first contact region
127 second contact region
130 light-generating regions
131 first connection post
132 second connection post
135 insulating carrier material
137 opening in insulating layer
140 first semiconductor layer
145 active zone
150 second semiconductor layer
151 first main surface of the second semiconductor layer
155 separating line
160 second current spreading layer
180 first current spreading layer
181 silver layer
182 conductive layer

1. An optoelectronic semiconductor component comprising an optoelectronic semiconductor chip configured to emit electromagnetic radiation; wherein the optoelectronic semiconductor comprises:
a first semiconductor layer of a first conductivity type;
a second semiconductor layer of a second conductivity type;
first and second current spreading layers;
a plurality of electrical connection elements; and
a plurality of first connection regions;
wherein:
the first semiconductor layer and the second semiconductor layer form a semiconductor layer stack;
the first current spreading layer is arranged on a side of the first semiconductor layer facing away from the second semiconductor layer;
the first current spreading layer is electrically connected to the first semiconductor layer;
the plurality of electrical connection elements is configured to electrically connect the second semiconductor layer to the second current spreading layer;
the first connection regions are connected to the first current spreading layer and extend through the second current spreading layer; and
an area coverage of the first connection regions in a region between adjacent parts of the second current spreading layer is greater than 20% of an area coverage of the second current spreading layer.

2. An optoelectronic semiconductor component comprising an optoelectronic semiconductor chip configured to emit electromagnetic radiation; wherein the optoelectronic semiconductor comprises:
a first semiconductor layer of a first conductivity type;
a second semiconductor layer of a second conductivity type;
first and second current spreading layers;
a plurality of electrical connection elements; and
a plurality of first connection regions;
wherein:
the first semiconductor layer and the second semiconductor layer form a semiconductor layer stack;
the first current spreading layer is arranged on a side of the first semiconductor layer facing away from the second semiconductor layer;
the first current spreading layer is electrically connected to the first semiconductor layer;
the plurality of electrical connection elements is configured to electrically connect the second semiconductor layer to the second current spreading layer;
the first connection regions are connected to the first current spreading layer and extend through the second current spreading layer; and
an area coverage of the first connection regions in an area between adjacent parts of the second current spreading layer is greater than 20% of an area coverage of the first current spreading layer.

3. The optoelectronic semiconductor component according to claim 1, wherein the second current spreading layer is configured to connect the plurality of electrical connection elements to one another.

4. The optoelectronic semiconductor component according to claim 1, wherein the second current spreading layer is partially designed as a grid.

5. The optoelectronic semiconductor component according to claim 1, wherein the semiconductor chip comprises a plurality of light-generating regions arranged between the electrical connection elements.

6. The optoelectronic semiconductor component according to claim 1, wherein the first connection regions are insulated from the second current spreading layer via an insulating layer.

7. The optoelectronic semiconductor component according to claim 1, in which wherein the first current spreading layer is arranged between the second current spreading layer and the first semiconductor layer.

8. The optoelectronic semiconductor component according to claim 1, further comprising a transparent substrate over the second semiconductor layer on a side facing away from the first semiconductor layer.

9. The optoelectronic semiconductor component according to claim 1, wherein part of the second current spreading layer is arranged outside the light-generating regions.

10. The optoelectronic semiconductor component according to claim 1, further comprising a first connection post electrically connected to the first connection regions, and a second connection post electrically connected to the second current spreading layer, the first and second connection posts being insulated from one another by an insulating carrier material.

11. The optoelectronic semiconductor component according to claim 1, further comprising a first contact region connected to the first current spreading layer, and a second contact region connected to the second current spreading layer wherein the first and the second contact regions are arranged in the region of a second main surface of the optoelectronic semiconductor component.

12. The optoelectronic semiconductor component according to claim 1, further comprising a first contact region directly adjoining the first connection regions, and a second contact region directly adjoining the second current spreading layer, the first contact region and the second contact region being arranged in the region of a second main surface of the optoelectronic semiconductor component.

13. The optoelectronic semiconductor component according to claim 1, further comprising a first contact region electrically connected to the first connection regions, and a second contact region electrically connected to the second current spreading layer, the second contact region being connectable from a first main surface of the optoelectronic semiconductor component and the first contact region being connectable from a second main surface of the optoelectronic semiconductor component.

14. The optoelectronic semiconductor component according to claim 1, further comprising a first contact region electrically connected to the first connection regions, and a second contact region electrically connected to the second current spreading layer the second and first contact regions being connectable from a first main surface of the optoelectronic semiconductor component.

15. The optoelectronic semiconductor component according to claim 1, further comprising a second contact region connected to the second current spreading layer and is arranged laterally spaced apart from the first contact region, wherein at least a part of the second contact region does not overlap vertically with the first semiconductor layer.

16. An optoelectronic semiconductor component comprising an optoelectronic semiconductor chip configured to emit electromagnetic radiation via a first main surface of the optoelectronic semiconductor component, and wherein the optoelectronic semiconductor component comprises:
a first semiconductor layer of a first conductivity type;
a second semiconductor layer of a second conductivity type;
first and second current spreading layers
a plurality of electrical connection elements, wherein:
the first semiconductor layer and the second semiconductor layer form a semiconductor layer stack;
the first current spreading layer is arranged on a side of the first semiconductor layer facing away from the second semiconductor layer;
the first current spreading layer is electrically connected to the first semiconductor layer;
the plurality of electrical connection elements configured to electrically connect the second semiconductor layer to the second current spreading layer;
further comprising a first contact region connected to the first current spreading layer, and a second contact region connected to the second current spreading layer, the second contact region being connectable from the first main surface of the optoelectronic semiconductor component and the first contact region being connectable from a second main surface of the optoelectronic semiconductor component.

17. (canceled)

18. The optoelectronic semiconductor component according to claim 16, wherein the second current spreading layer is configured to connect the plurality of electrical connection elements to one another and to the second contact region.

19-23. (canceled)

24. The optoelectronic semiconductor component according to claim 2, wherein the second current spreading layer is configured to connect the plurality of electrical connection elements to one another.

25. The optoelectronic semiconductor component according to claim 2, wherein the second current spreading layer is partially designed as a grid.

26. The optoelectronic semiconductor component according to claim 2, wherein the semiconductor chip comprises a plurality of light-generating regions arranged between the electrical connection elements.
